(19) United States
(12) Patent Application Publication
(10) Pub. No.: US 2019/0196285 A1
(43) Pub. Date: Jun. 27, 2019

(54) MANUFACTURING METHOD OF ARRAY SUBSTRATE AND ITS UPPER ELECTRODE LINE PATTERN AND LIQUID CRYSTAL DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventors: Zhichao ZHOU, Shenzhen (CN); Hui XIA, Shenzhen (CN); Meng CHEN, Shenzhen (CN)

(21) Appl. No.: 16/058,181

(22) Filed: Aug. 8, 2018

Related U.S. Application Data
(63) Continuation of application No. PCT/CN2018/072619, filed on Jan. 15, 2018.

(30) Foreign Application Priority Data
Dec. 26, 2017 (CN) 201711436209.2

(51) Int. Cl. G02F 1/1362; H01L 27/12; H01L 21/768; H01L 21/288

(52) U.S. Cl. CPC G02F 1/136286; H01L 27/124; H01L 27/1262; G02F 1/1368; H01L 21/7688; H01L 21/2885; H01L 21/76879

(57) ABSTRACT

The present invention provides a manufacturing method of an electrode line pattern of an array substrate, includes: depositing a buffering film on a substrate; forming a photoresist pattern on the substrate, having the buffering film thereon; dry etching an exposed portion of the buffering film exposed by the photoresist pattern to form a first buffering layer; sequentially depositing a second conductive buffering film and a first copper film; forming the electrode line pattern on an exposed portion of the first copper film on the substrate exposed by the photoresist pattern by an electroplating process; stripping off the photoresist pattern and layer thereon to obtain the electrode line pattern. The manufacturing method of the electrode line pattern can avoid problem of difficult to etch on a copper film and easy oxidation problem. The present invention also provides an array substrate and the liquid crystal display panel thereof.

### RELATED APPLICATIONS

The present application is a continuation application of PCT Patent Application No. PCT/CN2018/072619, filed Jan. 15, 2018, and claims the priority of China Application CN 201711436209.2, filed Dec. 26, 2017.

### FIELD OF THE DISCLOSURE

The present invention relates to a technical filed of display technology, specifically relates to manufacturing methods of an array substrate and its electrode line pattern and a liquid crystal display panel thereof.

### BACKGROUND

A thin film transistor liquid crystal display (TFT-LCD in short) has features of small size, low power consumption, zero radiation, and so forth, and thus currently occupies leading position in the flat panel display market. TFT-LCD is formed by an array substrate and an aligned color filter substrate, wherein the array substrate includes an underlay substrate and a conductive pattern and a dielectric layer formed thereon. The conductive pattern includes a source line, a data line, a gate line, a drain line, and etc., to improve contrast and image displaying quality of the TFT-LCD. In general, such source and data lines for formed by copper having a characteristics of low electrical resistance.

However, in the conventional fabrication of an array substrate, copper source and data lines are directly exposed to the air and oxidized easily. Moreover, f wet etching is usually used to fabricate the electrode pattern, but is not sufficient to form accurate copper pattern. The copper film formed thereby usually has a slope, as shown in FIG. 1 circled in red, and thus the top and bottom surfaces of the copper film are not perfectly aligned leading to critical dimension loss. As shown in FIG. 1, the circled sidewalls are also thinner and easily to break leading to defect of break line. Product yield of the array substrate is therefore affected and copper application in TFT-LCD is also severely limited.

### SUMMARY

In view of this, an embodiment of the present invention provides a manufacturing method of an electrode line pattern of an array substrate, an array substrate and a liquid crystal display panel in order to improve fabrication result of the electrode line pattern on the array substrate and also to reduce oxidation defect of the copper electrode line.

A first aspect of the present invention provides a manufacturing method of an electrode line pattern of an array substrate, including : depositing a buffering film on a substrate; forming a photoresist pattern on the substrate, having the buffering film thereon, by a patterning process, wherein an exposed portion of the substrate exposed by the photoresist pattern corresponds to a zone of an electrode line pattern to be formed, which is going to be formed; removing an exposed portion of the buffering film exposed by the photoresist pattern by a dry etching process to form a first buffering layer under the photoresist pattern; sequentially depositing a second conductive buffering film and a first copper film on the substrate, having the first buffering layer and the photoresist pattern formed thereon; forming an electrode line pattern on an exposed portion of the first copper film on the substrate exposed by the photoresist pattern by an electroplating process, wherein the electrode line pattern is made by copper, and the electrode line pattern is a gate line and/or a gate, or a data line and/or a source/drain; and stripping off the photoresist pattern on the substrate and the second conductive buffering layer and the first copper film on the photoresist pattern to form the electrode line pattern intervally disposed in-between the first buffering layer.

Wherein the step of “forming an electrode line pattern on an exposed portion of the first copper film on the substrate exposed by the photoresist pattern by an electroplating process” includes: connecting the exposed portion of the first copper film on the substrate exposed by the photoresist pattern to a cathode of an electrolytic cell, connecting a copper target to an anode of the electrolytic cell, connecting the cathode and the anode of the electrolytic cell via copper-containing electrolyte, applying electric current between the cathode and the anode of the electrolytic cell, and electroplating a default time period to receive the electrode line pattern.

Wherein a distance between the substrate and a surface of the electrode line pattern away from the substrate is equal to a distance between the substrate and a surface of the first buffering layer away from the substrate.

Wherein a thickness of the second conductive buffering layer is less than 20% of a thickness of the first buffering layer, and a thickness of the first copper film is less than 20% of a thickness of the first buffering layer.

Wherein material of the second conductive buffering layer includes at least one of molybdenum (Mo), titanium (Ti), tantalum (Ta), molybdenum titanium alloy, molybdenum niobium alloy, molybdenum tantalum alloy, titanium nitride, and indium tin oxide, a thickness of the second conductive buffering layer is in a range of 10-60 nm; and a thickness of the first copper film is in a range of 10-100 nm. The second conductive buffering layer is mainly for improving binding capacity between the first copper film and the substrate, and thus the thinner first copper film can be used to electroplate to form a certain thickness of the electrode line pattern later in the process. Moreover, the second conductive buffering layer and the first copper film both have less thicknesses for easier stripping off the photoresist pattern, the second conductive buffering layer thereon, and the first copper film, and so that residues of those three can be reduced.

Wherein a thickness of the first buffering layer is in a range of 50-1000 nm, material of the first buffering layer includes at least one of silicon nitride, silicon oxide and aluminum oxide. The first buffering layer is a dielectric coating layer that it is easier to perform the electroplating process intervally in-between the first buffering layer and the first copper film; and also, it allows accurate control of alignment of the top and bottom surfaces of the first buffering layer in formation of the first buffering layer by the dry etching process, no taper is formed can also indirectly control a shape of the electrode line pattern.

Wherein a thickness of the photoresist pattern is in a range of 1.5-5 μm.

Wherein a protection layer is further formed on the electrode line pattern, a distance between the substrate and a surface of the protection layer away from the substrate is equal to a distance between the substrate and a surface of the first buffering layer away from the substrate.

In the manufacturing method of an electrode line pattern of an array substrate provided by the present invention, the buffering film and the photoresist pattern are sequentially formed on the substrate, an exposed portion of the buffering film exposed by the photoresist pattern is target to the dry etching process, the first buffering layer is formed under the photoresist pattern, the exposed portion of the substrate exposed by the photoresist pattern and the first buffering layer corresponds to (aligned to) the zone of the electrode line pattern going to be formed; then the thin second conductive buffering film and the thin first copper film are sequentially deposited on the substrate; after, only the first copper film on the substrate exposed by the photoresist pattern is targeted to the electroplating process to form the electrode line pattern; and the electrode line pattern is received by stripping off the photoresist pattern and the coating layers thereon. In the manufacturing method, the electrode line pattern is intervally disposed in-between the first buffering layer that sidewalls of the electrode line pattern can be well protected, and possibility of oxidation can also be reduced. The electrode line pattern is fabricated by the electroplating process and bad results by etching copper directly as in the conventional method can be avoided; also, shape of the electrode line pattern can be indirectly controlled by the dry etching process targeted to the first buffering layer so as to accurately obtain the aligned top and bottom surfaces, and nearly zero critical dimension loss, of the copper electrode line pattern. Thus, possibility of point discharge of the electrode line pattern can be reduced, and thereby break line damages on the slope of other coating layers formed on the electrode line pattern can also prevent.

A second aspect of the present invention provides an array substrate, including: a substrate; and a first buffering film, a second conductive buffering film, a first copper film, and an electrode line pattern disposed on the substrate; wherein the second conductive buffering layer, the first copper film and the electrode line pattern are sequentially stacked on an exposed portion of the substrate exposed by the first buffering layer, a top surface of the electrode line pattern and a top surface of the first buffering layer are aligned (or coplanar); and the electrode line pattern is made by copper, and the electrode line pattern is a gate line and/or a gate, or a data line and/or a source/drain.

In the array substrate of the present invention, the electrode line pattern is intervally disposed in-between the first buffering layer that sidewalls of the electrode line pattern can be well protected, and possibility of oxidation can also be reduced. Alignment of the top and bottom surfaces of the electrode line pattern is improved and thus possibility of point discharge of the electrode line pattern can be reduced, and thereby break line damages on the slope of other coating layers formed on the electrode line pattern can also prevent.

A third aspect of the present invention provides a liquid crystal display panel and the liquid crystal display panel includes a color filter substrate and an array substrate disposed opposite to each other, and a liquid crystal layer, sandwiched between the color filter substrate and the array substrate, wherein the array substrate is as manufactured by the first aspect of or as described in the second aspect of the present invention.

Advantages of the present invention are illustrated in the following discretion. It is clearly showed in the specification or can be received by the embodiments of the present invention.

### BRIEF DESCRIPTION OF THE DRAWINGS

FIG. 1 is a schematic view according to the conventional technology before and after a copper film etching process. 100 is a substrate, 200 is the copper film, 200′ is the copper film after the etching process, and 300 is a photoresist;

FIG. 2 is a flow chart of an electrode line pattern of an array substrate according to an embodiment of the present invention;

FIG. 3 is a schematic view of the substrate having the buffering film formed thereon in the step S10;

FIG. 4 is a structural schematic view of the substrate having the photoresist pattern formed thereon in the step S20;

FIG. 5 is a structural schematic view of the substrate having the photoresist pattern formed thereon in the step S30;

FIG. 6 is a structural schematic view of the substrate having the second conductive buffering layer and the first copper film formed thereon in the step S40;

FIG. 7 is a top view of FIG. 6;

FIG. 8 is a cross sectional view of the substrate having the electrode line pattern formed thereon after the step 50 as shown in FIG. 6;

FIG. 9 is a structural schematic view of the array substrate after stripping off the photoresist and the coating layers thereon as shown in FIG. 8;

FIG. 10 is a plane graph after formation of the copper gate and the gate line; and

FIG. 11 is a structural schematic view of the array substrate according to another embodiment of the present invention.

Element number in the figures: 1—substrate; 2—buffering film; 2′—first buffering layer; 3—photoresist pattern; 4—second conductive buffering layer; 5—first copper film; 6—electrode line pattern; 7—protection payer; and 51—exposed portion of the first copper film on the substrate 1 exposed by the photoresist pattern 3.

### DETAILED DESCRIPTION OF PREFERRED EMBODIMENTS

The following illustrates preferred embodiments of the present invention. And it should be stated out any modifications or perfections of the invention by an ordinary skilled person in the art, without departing from the spirit of the present invention, are still within the scope of protection of the present application.

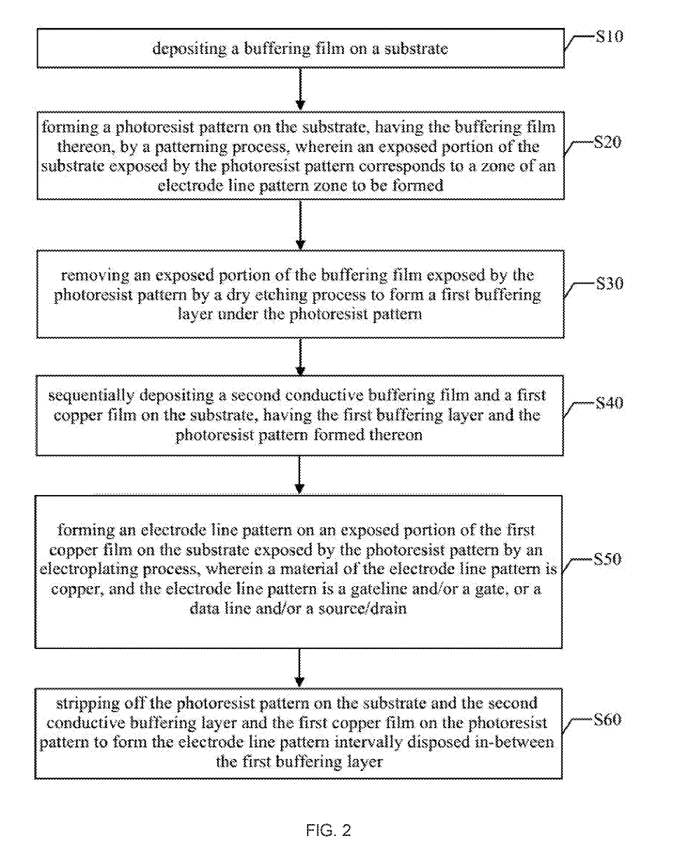

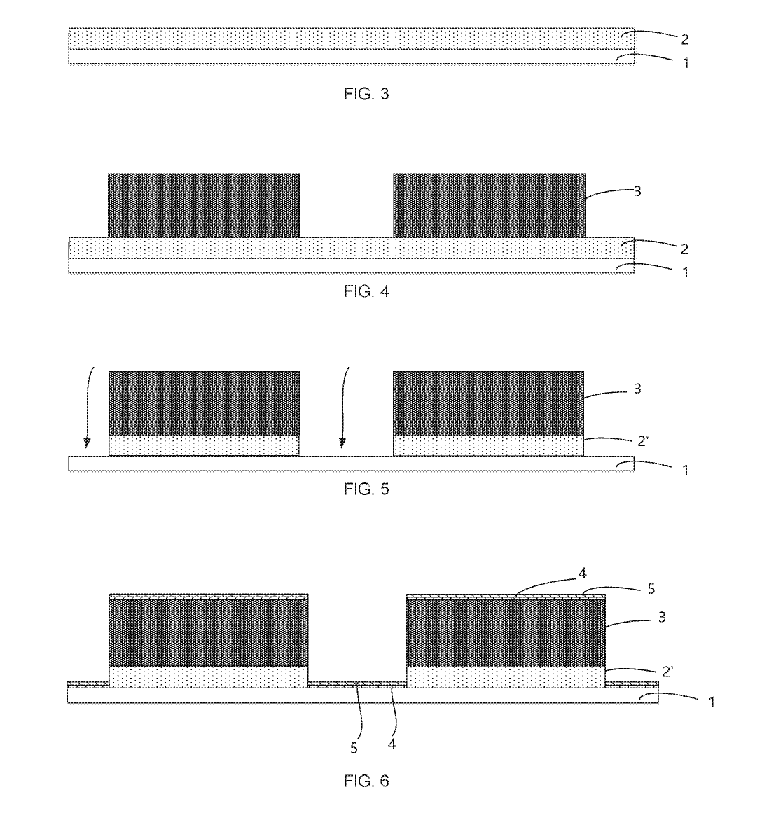

Please refer to FIG. 2-FIG. 9 together, an embodiment of the present invention provides a manufacturing method of an electrode line pattern of an array substrate, including: S10. as shown in FIG. 3, depositing a buffering film 2 on a substrate 1; S20. as shown in FIG. 4, forming a photoresist pattern 3 on the substrate 1, having the buffering film 2 thereon, by a patterning process; wherein an exposed portion of the substrate 1 exposed by the photoresist pattern 3 corresponds to a zone of an electrode line pattern 6 to be formed; S30. as shown in FIG. 5, removing an exposed portion of the buffering film 2 exposed by the photoresist pattern 3 by a dry etching process to form a first buffering film 2′; S40. as shown in FIG. 6, sequentially depositing a second conductive buffering film 4 and a first copper film 5 on the substrate 1, having the first buffering layer 2′ and the photoresist pattern 3 formed thereon; S50. as shown in FIG. 8, forming an electrode line pattern 6 on an exposed portion of the first copper film 5 on the substrate 1 exposed by the photoresist pattern 3 by an electroplating process, wherein a material of the electrode line pattern 6 is copper, and the electrode line pattern 6 is a gate line and/or a gate, or a data line and/or a source/drain; and S60. as shown in FIG. 9, stripping off the photoresist pattern 3 on the substrate 1 and the second conductive buffering layer 4 and the first copper film 5 on the photoresist pattern 3 to form the electrode line pattern 6 intervally disposed in-between the first buffering layer 2′.

In the manufacturing method of the present invention, in the step S10, material of the substrate 1 is not limited herein; and it can be a glass substrate or a flexible substrate. When a cleanliness of the substrate 1 does not reach the requirement, a pre-cleaning process is performed to the substrate 1.

As shown in FIG. 3, the buffering film 2 covers the entire substrate 1, and it can be formed by a coating technique, such as chemical vapor deposition (CVD) and physical vapor deposition (PVD). Wherein CVD includes but not limits to hot filament chemical vapor deposition, plasma-enhanced chemical vapor deposition (PECVD), and etc. Physical vapor deposition includes but not limits to magnetron sputtering, vacuum evaporation, ion plating (e.g. arc ion plating and RF ion plating), and etc. And preferably, CVD is used to form the buffering film.

The buffering film 2 can be a single or multiple layer structure. Exemplarily, when the buffering film 2 is a single layer structure, it can be silicon oxide (SiOx) or silicon nitride (SiNx) or aluminum oxide (Al₂O₃). When the buffering film 2 is a dual-layer structure or more than two layers, it can be a stack structure of silicon oxide (SiOx) and silicon nitride (SiNx), or a stack structure of silicon oxide (SiOx), silicon nitride (SiNx) and aluminum oxide (Al₂O₃). Optionally, a thickness of the buffering film 2 is in a rage of 50-1000 nm.

In the step S20, an exposed portion of the substrate 1 exposed by the photoresist pattern 3 corresponds to the zone of the electrode line pattern 6, which is going to be formed; and that is, shapes of the photoresist pattern 3 and the electrode line pattern 6 are complementary to each other. For example, when the zone of electrode line pattern 6 is agate and a gate line, the shape of the photoresist pattern 3 is complementary to the shapes of the gate and gate line.

Optionally, a thickness of the photoresist pattern 3 is in a range of 1.5-5 μm. The photoresist pattern 3 is thicker to form a sharp step that easier for the layers on the photoresist to separate from the layers underlay the photoresist. For instance, it can efficiently prevent electrical connection between the portion of the first copper film 5 on the photoresist pattern 3 and the exposed portion the first copper film 5 exposed by the photoresist pattern 3 on the substrate 1.

The photoresist pattern 3 is light-sensitive lacquer material, and it can be a positive or a negative photoresist. The patterning process is a technology to remove a portion out of the entire material layer left the rest portion of the layer being of the desired structure. It usually includes one or more steps of coating, mask exposing, baking, developing, etching, peeling, and etc.

Exemplarily, “forming a photoresist pattern 3 on the substrate 1, having the buffering film 2 thereon, by a patterning process”in the step S20 includes: S201. coating a photoresist layer on the buffering film 2 on the substrate 1; and S202. exposing the photoresist layer, and developing to remove the portion of the photoresist corresponding to (aligned to) the electrode line pattern 6 to obtain the photoresist pattern 3.

As shown in FIG. 4, via the patterning process in the step S20, the exposed portion of the substrate 1 exposed by the photoresist pattern 3 (i.e. grooves in-between the photoresist pattern 3) corresponds to the zone of electrode line pattern going 6 to be formed. The electrode line pattern 6 can be a single gate line pattern, single gate pattern or gate lines pattern and gates pattern, and it can be achieved by adjusting the mask in the exposing process. Preferably, the electrode line pattern 6 is gate line pattern and gate pattern; so that the photoresist corresponding to the gate line and gate can be removed together in the exposure and development and to electroplate to form the gate line and gate concurrently in the consequent step.

Similarly, when the electrode line pattern 6 is data line and/or source/drain, the portion of the photoresist layer corresponding to the source and drain is removed in the patterning process, and accordingly, the portion of the photoresist layer corresponding to the data line is also removed.

In the step S30, the first buffering layer 2′ by the dry etching process targeted to the buffering film 2. On one hand, it is easier to form a dielectric buffering film 2 being neat and regulated, having aligned top and bottom surfaces and without taper corners (no slope) by a dry etching process; and on the other hand, shapes of sidewalls of the first buffering layer 2′ significantly influences shape of the electrode line pattern formed later in the method, and thus detailed structure of the electrode line pattern 6 can be indirectly controlled by adjusting the shape of the first buffering layer 2′.

After the step S30, the exposed portion of the substrate 1 exposed by the stack of the first buffering layer 2′ and the photoresist pattern 3 (as indicated by the arrows in FIG. 5) corresponds to the zone of the electrode line pattern 6 going to formed. The projection of the first buffering layer 2′ on the substrate is covered by the projection of the photoresist pattern 3 on the substrate 1, and sizes of the two projections are equal. Moreover, a thickness and material of the first buffering layer 2′ are the same as the buffering film 2 illustrated above, and it is omitted herein for the purpose of brevity.

Optionally, the etching gas of the dry etching process include fluorine-containing and hydrogen gases, and a flow rate of fluorine-containing gas to hydrogen is in a range of 5-15:1; for example, the ratio can be 6:1, 8:1, 10:1 or 12:1. Hydrogen can inhibit etching ability of fluorine-containing gas to the substrate.

Optionally, the fluorine-containing gas includes at least one of CF₄ and SF₆. Optionally, the etching gas includes CF₄ and hydrogen or includes SF₆ and hydrogen. Optionally, a flow rate of the fluorine-containing gas is in a range of 100 sccm-500 sccm; wherein sccm is under the standard condition, that is, 1 standard atmosphere 25 degrees Celsius 1 cubic centimeter per minute (1 ml/min).

Optionally, in the dry etching process, the atmospheric pressure is in a range of 100-4000 mtorr, gas source power is in a range of 400-800 W, bias voltage is in a range of 100-200V. Wherein, a time period for performing the dry etching process depends on the thickness of the buffering film 2 and the flow rate of the etching gas. The principle of the dry etching is: under the plasma technology the etching gas becomes isotropic, the isotropic plasma dry etches the buffering film 2. More specifically, a plasma generator is used prepare the isotropic plasma under conditions of air pressure in a rage of 100-4000 mtorr, gas source power in a range of 400-800 W, and bias voltage in a range of 100-200V.

In the step S40, the second conductive buffering layer 4 and the first copper film 5 both have less thickness. Optionally, a thickness of the second conductive buffering layer 4 is in a range of 10-60 nm. A thickness of the first copper film 5 is in a range of 10-100 nm. The second conductive buffering layer 4 and the first copper film 5 can be formed by the above CVD or PVD. Preferably, both are formed by PVD. The second conductive buffering layer 4 is mainly for enhancing binding capacity between the first copper film 5 and the substrate 1, and thus the thinner first copper film 5 can be used to electroplate to form a certain thickness of the electrode line pattern 6 later in the process.

As shown in FIG. 6, in the processes of sequential formation of the second conductive buffering layer 4 and the first copper film 5, they do not just formed on the photoresist pattern 3 but also on the exposed portion of the substrate, which is exposed by the photoresist pattern 3. However, it is clear that there is no electrical connection between the portion of the first copper film 5 on the photoresist pattern 3 and the exposed portion the first copper film 5 exposed by the photoresist pattern 3 on the substrate 1.

Optionally, material of the second conductive buffering layer includes at lent one of molybdenum (Mo), titanium (Ti), molybdenum titanium alloy (MoTi), molybdenum niobium alloy (MoNb), tantalum (Ta), molybdenum tantalum alloy (MoTa), titanium nitride (TiN), indium tin oxide (ITO), indium zinc oxide (IZO), aluminum-doped zinc oxide (AZO), fluorine-doped tin dioxide (FTO) and phosphorus-doped tin dioxide (PTO), but it is not limited herein.

Optionally, a thickness of the second conductive buffering layer 4 or the first copper film 5 is less than 20% of a thickness of the first buffering layer 2′.

Optionally, projections of the electrode line pattern, the second conductive buffering layer and the first copper film on the substrate are the same.

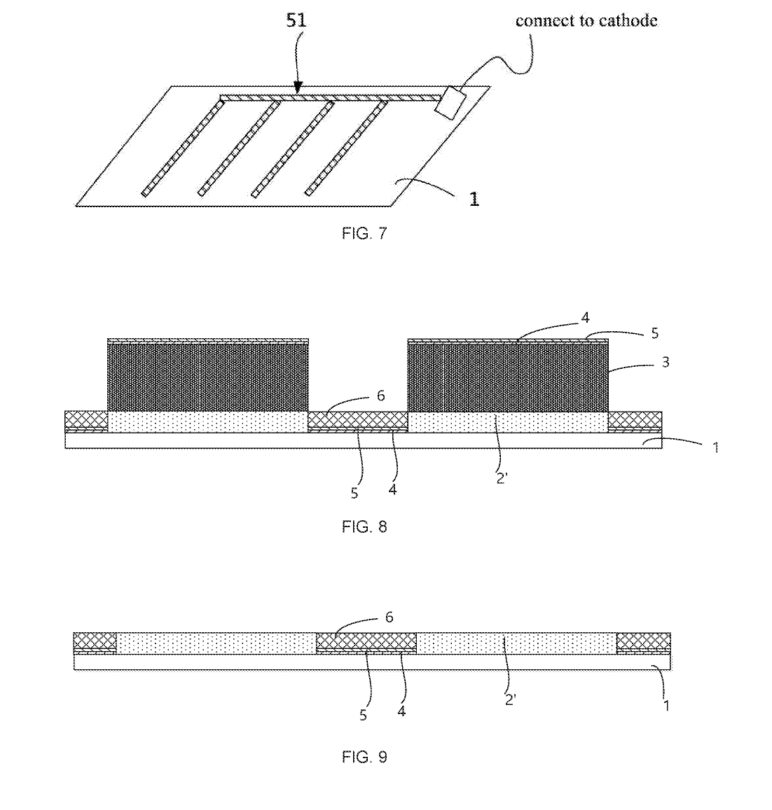

In the manufacturing method of the present invention, in the step S50, “forming an electrode line pattern on an exposed portion of the first copper film on the substrate exposed by the photoresist pattern by an electroplating process”includes: connecting the exposed portion of the first copper film 5 on the substrate exposed by the photoresist pattern 3 (as labeled 51 in FIG. 7) to a cathode of an electrolytic cell, connecting a copper target to an anode of the electrolytic cell, connecting the cathode and an anode of the electrolytic cell via copper-containing electrolyte, applying electric current between the cathode and the anode of the electrolytic cell, electroplating a default time period to receive the electrode line pattern 6.

Optionally, the copper-containing electrolyte includes salt and acid which containing copper ion, e.g. mixed solution of CuSO₄ and H₂SO₄. In the electroplating process, a thickness and uniformity of the deposited electrode line pattern 6 can be controlled by adjusting solution concentration of the electrolyte, density of electrical current, and time period of the electroplating.

In the electroplating process of the present invention, the metal going to electroplate is the cathode, copper ions are going to form a strong adhesive compact thin film on the exposed portion of the first copper film 5 on the substrate 1 exposed by the photoresist pattern 3 under the function of electrical current (i.e. on the first copper film 5 in the zone of the electrode line pattern 6 to be formed, labeled as 51 in FIG. 7), and this portion of the second copper film is the electrode line pattern 6. There is no copper thin film formed on the rest portion of the first copper film 5 on the photoresist pattern 3 because there is no electrical current passed through. Obviously, in the embodiments of the present invention, there is no need for expensive copper acid etching to form the electrode line pattern 6 with accurate structure. Thus problem of difficult to etch on a copper film can also be avoided, and also cost on etching equipment can also be saved.

Preferably, if the photoresists corresponding to the gate and gate line are together removed in the step S202, gate and gate line pattern is formed concurrently in the step S50.

In the step S60, in “stripping off the photoresist pattern 3 and the second conductive buffering layer 4 and the first copper film 5 thereon on the substrate)”, it can use a common copper stripper. The copper stripper is mainly for stripping the photoresist pattern 3, and also the second conductive buffering layer 4 and the first copper film 5 on the photoresist pattern 3, off. As above illustrated, due to less thicknesses of the second conductive buffering layer 4 and the first copper film 5, it is not difficult to strip off and less stripper is used in the step S60. There are nearly zero residues in the stripper. Meanwhile, the copper made electrode line pattern 6 is not affected thereby.

Optionally, the stripper includes isopropanol and copper sulfate, or isopropanol and copper bisulfite and sulfuric acid, or isopropanol and sulfurous acid; wherein, a weight percentage of copper sulfate, or copper bisulfite and sulfuric acid, or sulfurous acid is equal to or less than 5%.

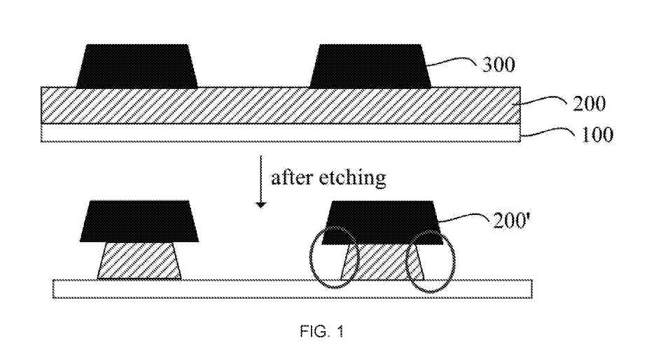

In the manufacturing method of the electrode line pattern on the array substrate of present invention provided above, the final copper electrode line pattern 6 is intervally disposed in-between the first buffering layer 2′ (as shown in FIG. 9), sidewalls of the copper electrode line pattern 6 can be well protected, and possibility of oxidation can also be reduced. The copper electrode line pattern 6 is fabricated by electroplating technique, and bad results by etching copper directly as in the conventional method can be avoided: also, shape of the electrode line pattern (including taper corner (slope angle) and critical dimension loss (CD Loss)) can all be accurately controlled by the dry etching process targeted to the first buffering layer 2′; as shown in FIG. 9, the top and bottom surfaces, and sidewalls of the electrode line pattern 6 are neat and flat, and the top and bottom surfaces are aligned and even, and the sidewalls are nearly completely vertical to the substrate. Up the surface of the substrate, cross sectional surface of the electrode line pattern 6 is regulated (unchanged), and nearly no critical dimension loss. The structure of the electrode line pattern 6 in FIG. 9 can avoid possibility of point discharge (structure of FIG. 1 has possibility of point discharge), and thereby break line damages on the slope of other coating layers formed on the electrode line pattern can also prevent.

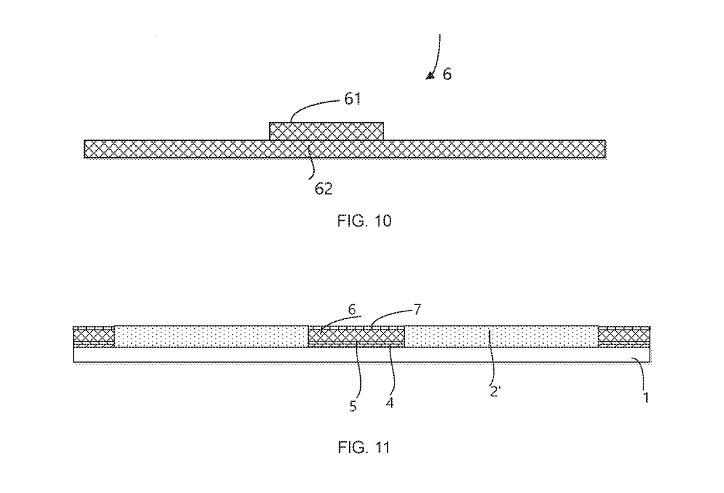

When the electrode line pattern 6 in FIG. 9 is gate line and/or gate, the array substrate is a bottom gate thin film transistor array substrate. And sectional plane view of the electrode line pattern 6 is as shown in FIG. 10, wherein the electrode line pattern 6includes gate 61 and gate line 62, and a gate dielectric layer, active layer, source, drain, and so forth can be formed thereon. When the electrode line pattern 6 in FIG. 9 is data line and/or source/drain, the array substrate is atop gate thin film transistor array substrate.

In FIG. 9, a distance between the substrate 1 and a surface of the electrode line pattern 6 away from the substrate 1 is equal to a distance between the substrate 1 and a surface of the first buffering layer 2′ away from the substrate 1; that is, the top surface of the electrode line pattern 6 is aligned (coplanar) to the top surface of the first buffering layer 2′.

At meanwhile, a total thickness of the second conductive buffering layer 4, the first copper film 5 and the electrode line pattern 6 is equal to a thickness of the first buffering layer 2′. At meanwhile, the top surface of the array substrate is flatter and easier for formation of other coating layer thereon, and break line damages on the slope of other coating layers can also prevent.

Optionally, in other embodiments of the present invention (as shown in FIG. 11), a protection payer 7 can be formed on the electrode line pattern 6. A distance between the substrate 1 and a surface of the protection payer 7 away from the substrate is equal to a distance between the substrate 1 and a surface of the first buffering layer 2′ away from the substrate 1; that is, the top surface of the protection payer 7 is aligned(coplanar) to the top surface of the first buffering layer 2′. In other words, the total thickness of the second conductive buffering layer 4, the first copper film 5 and the electrode line pattern 6, the protection payer 7 is equal to the thickness of the first buffering layer 2′. In this condition, when the electrode line pattern 6 is formed by electroplating, a distance between the substrate 1 and the surface of the electrode line pattern 6 away from the substrate is certainly less than a distance between the substrate 1 and the surface of the first buffering layer 2′ away from the substrate 1.

The protection payer 7 can further prevent oxidation of the top surface of the copper electrode line pattern 6 in the following manufacturing steps, and almost has no influences on electrical conductivity of the electrode line pattern 6. Optionally, the protection payer 7 can be chromium, molybdenum, aluminum, silver, and so on. The protection payer 7 can be formed by electroplating after the electroplating process of the copper electrode line pattern 6.

Another embodiments of the present invention also provides an array substrate, the structural schematic view of the array substrate is as shown in FIG. 9. The array substrate includes a substrate, and a first buffering film 2′, a second conductive buffering film 4, a first copper film 5, and an electrode line pattern 6 disposed on the substrate 1; wherein the second conductive buffering layer 4, the first copper film 5 and the electrode line pattern 6 are disposed sequentially on the exposed portion of the substrate) exposed by the first buffering layer 2′, and the top surface of the electrode line pattern 6 is aligned (coplanar) to the top surface of the first buffering layer 2′; and the electrode line pattern 6 is copper.

From FIG. 9, it shows the electrode line pattern 6 is intervally disposed in-between the first buffering layer 2′, all sidewalls of the electrode line pattern 6 are embedded in the first buffering layer 2′ for good protection and reduction of possibility of oxidation. In addition, the top and bottom surfaces of the electrode line pattern 6 are flat and aligned to each other so as to reduce point discharge, and thereby break line damages on the slope of other coating layers formed thereon can also prevent.

Optionally, the total thickness of the second conductive buffering layer 4, the first copper film 5 and the electrode line pattern 6 is equal to the thickness of the first buffering layer 2′. The top surface of the electrode line pattern 6 is aligned (or coplanar) to the top surface of the first buffering layer 2′.

Optionally, further a protection payer 7 is formed on the electrode line pattern 6, and in this case, the total thickness of the second conductive buffering layer 4, the first copper film 5 and the electrode line pattern 6, the protection payer 7 is equal to the thickness of first buffering layer 2′.

Another embodiment of the present invention also provides a liquid crystal display panel, and the liquid crystal display panel includes a color filter substrate and an array substrate disposed opposite to each other and a liquid crystal layer sandwiched between the color filter substrate and the array substrate. A structure of the array substrate is as shown in FIGS. 9-11.

Incidentally, according to the above-disclosed and set forth in the description, those skilled in the art of the present invention may further make changes and modifications to the above embodiments. Accordingly, the present invention is not limited to the above specific embodiments disclosed and described herein, some equivalent modifications and variations of the present invention may also be within the scope of protections of the claims of the present invention. Further, despite the use of certain terms used in this specification, they are used for convenience only and do not constitute any limitation to the present invention.

What is claimed is:

1. A manufacturing method of an electrode line pattern of an array substrate, comprising:
depositing a buffering film on a substrate;
forming a photoresist pattern on the substrate, having the buffering film thereon, by a patterning process, wherein an exposed portion of the substrate exposed by the photoresist pattern corresponds to a zone of the electrode line pattern to be formed;
removing an exposed portion of the buffering film exposed by the photoresist pattern by a dry etching process to form a first buffering layer under the photoresist pattern;
sequentially depositing a second conductive buffering film and a first copper film on the substrate, having the first buffering layer and the photoresist pattern formed thereon;
forming the electrode line pattern on an exposed portion of the first copper film on the substrate exposed by the photoresist pattern by an electroplating process, wherein a material of the electrode line pattern is copper, and the electrode line pattern is a gate line and/or a gate, or a data line and/or a source/drain; and
stripping off the photoresist pattern on the substrate and the second conductive buffering layer and the first copper film on the photoresist pattern to form the electrode line pattern intervally disposed in-between the first buffering layer.

2. The manufacturing method according to claim 1, wherein the step of “forming an electrode line pattern on an exposed portion of the first copper film on the substrate exposed by the photoresist pattern by an electroplating process” includes:
connecting the exposed portion of the first copper film on the substrate exposed by the photoresist pattern to a cathode of an electrolytic cell, connecting a copper target to an anode of the electrolytic cell, connecting the cathode and the anode of the electrolytic cell via copper-containing electrolyte, applying electric current between the cathode and the anode of the electrolytic cell, and electroplating a default time period to receive the electrode line pattern.

3. The manufacturing method according to claim 1, wherein a thickness of the photoresist pattern is in a range of 1.5-5 μm,

4. The manufacturing method according to claim 1, wherein a thickness of the second conductive buffering layer is less than 20% of a thickness of the first buffering layer, and a thickness of the first copper film is less than 20% of a thickness of the first buffering layer.

5. The manufacturing method according to claim 1, wherein material of the second conductive buffering layer includes at least one of molybdenum (Mo), titanium (Ti), tantalum (Ta), molybdenum titanium alloy, molybdenum niobium alloy, molybdenum tantalum alloy, titanium nitride, and indium tin oxide, and a thickness of the second conductive buffering layer is in a range of 10-60 nm.

6. The manufacturing method according to claim 1, wherein a thickness of the first buffering layer is in a range of 50-1000 nm, and material of the first buffering layer includes at least one of silicon nitride, silicon oxide and aluminum oxide.

7. The manufacturing method according to claim 4, wherein a thickness of the first copper film is in a range of 10-100 nm.

8. The manufacturing method according to claim 1, wherein a distance between the substrate and a surface of the electrode line pattern away from the substrate is equal to a distance between the substrate and a surface of the first buffering layer away from the substrate.

9. The manufacturing method according to claim 8, wherein projections of the electrode line pattern, the second conductive buffering layer and the first copper film on the substrate are the same.

10. The manufacturing method according to claim 1, wherein a protection layer is further formed on the electrode line pattern, a distance between the substrate and a surface of the protection layer away from the substrate is equal to a distance between the substrate and a surface of the first buffering layer away from the substrate.

11. The manufacturing method according to claim 10, wherein the protection layer is at least one of chromium, molybdenum, aluminum, and silver.

12. An array substrate, comprising:
a substrate; and
a first buffering layer, a second conductive buffering film, a first copper film, and an electrode line pattern disposed on the substrate, wherein the second conductive buffering layer, the first copper film and the electrode line pattern are sequentially stacked on an exposed portion of the substrate exposed by the first buffering layer, the electrode line pattern is made by copper, and the electrode line pattern is a gate line and/or a gate, or a data line and/or a source/drain.

13. The array substrate according to claim 12, wherein a thickness of the second conductive buffering layer is less than 20% of a thickness of the first buffering layer, and a thickness of the first copper film is less than 20% of a thickness of the first buffering layer.

14. The array substrate according to claim 12, wherein a thickness of the first buffering layer is in a range of 50-1000 nm, material of the first buffering layer includes at least one of silicon nitride, silicon oxide and aluminum oxide.

15. The array substrate according to claim 12, wherein material of the second conductive buffering layer includes at least one of molybdenum (Mo), titanium (Ti), tantalum (Ta), molybdenum titanium alloy, molybdenum niobium alloy, molybdenum tantalum alloy, titanium nitride, and indium tin oxide, and a thickness of the second conductive buffering layer is in a range of 10-60 nm.

16. The array substrate according to claim 12, wherein projections of the second conductive buffering layer and the first copper film on the substrate are the same.

17. The array substrate according to claim 12, wherein a total thickness of the second conductive buffering layer, the first copper film and the electrode line pattern is equal to a thickness of the first buffering layer.

18. The array substrate according to claim 12, wherein a protection layer is further disposed on the electrode line pattern, and a total thickness of the second conductive buffering layer, the first copper film, the electrode line pattern and the protection layer is equal to a thickness of the first buffering layer.

19. A liquid crystal display panel, comprising:
a color filter substrate;
an array substrate disposed opposite to the color filter substrate; and
a liquid crystal layer, sandwiched between the color filter substrate and the array substrate;
wherein the array substrate comprises:
a substrate; and a first buffering layer, a second conductive buffering film, a first copper film, and an electrode line pattern all disposed on the substrate; and
wherein the second conductive buffering layer, the first copper film and the electrode line pattern are sequentially stacked on an exposed portion of the substrate exposed by the first buffering layer, the electrode line pattern is made by copper, and the electrode line pattern is a gate line and/or a gate, or a data line and/or a source/drain.

20. The liquid crystal display panel according to claim 19, wherein a thickness of the second conductive buffering layer is less than 20% of a thickness of the first buffering layer, and a thickness of the first copper film is less than 20% of a thickness of the first buffering layer.
